(19) United States
(12) Patent Application Publication
(10) Pub. No.: US 2012/0051381 A1
(43) Pub. Date: Mar. 1, 2012

(54) METHOD OF MANUFACTURING SEMICONDUCTOR LASER APPARATUS, SEMICONDUCTOR LASER APPARATUS AND OPTICAL APPARATUS

(75) Inventors: Gen Shimizu, Tottori-shi (JP); Shinichiro Akiyoshi, Kurayoshi-shi (JP); Daiki Mihashi, Tottori-shi (JP)

(73) Assignees: SANYO Optec Design Co., Ltd., Bunkyo-ku (JP); Sanyo Electric Co., Ltd., Moriguchi-shi (JP)

(21) Appl. No.: 13/220,774

(22) Filed: Aug. 30, 2011

(30) Foreign Application Priority Data
Aug. 30, 2010 (JP) 2010-192185

(51) Int. Cl. H01S 5/02; H01L 31/18

(52) U.S. Cl. 372/50.1; 438/26; 257/E33.057

(57) ABSTRACT

This method of manufacturing a semiconductor laser apparatus includes steps of forming a first solder layer on a first electrode, forming a second solder layer with a second melting point on a second electrode through a barrier layer, forming a reaction solder layer with a third melting point higher than the second melting point by reacting the first solder layer having a first melting point with the first electrode and bonding a first semiconductor laser device to a base through the reaction solder layer, and bonding a second semiconductor laser device by melting the second solder layer with the second melting point after the step of bonding the first semiconductor laser device.

### CROSS-REFERENCE TO RELATED APPLICATION

The priority application number JP2010-192185, Method of Manufacturing Semiconductor Laser Apparatus, Semiconductor Laser Apparatus and Optical Apparatus, Aug. 30, 2010, Gen Shimizu et al., upon which this patent application is based is hereby incorporated by reference.

### BACKGROUND OF THE INVENTION

1. Field of the Invention

The present invention relates to a method of manufacturing a semiconductor laser apparatus, a semiconductor laser apparatus and an optical apparatus, and more particularly, it relates to a method of manufacturing a semiconductor laser apparatus having a first semiconductor laser device and a second semiconductor laser device both bonded to a base, a semiconductor laser apparatus and an optical apparatus.

2. Description of the Background Art

A method of manufacturing a semiconductor laser apparatus having a first semiconductor laser device and a second semiconductor laser device both bonded to a base is known in general, as disclosed in Japanese Patent Laying-Open No. 2000-268387, for example.

Japanese Patent Laying-Open No. 2000-268387 discloses a semiconductor light source module having light source chips bonded onto an upper surface of a silicon substrate with different types of solder having different melting points from each other. A method of manufacturing this semiconductor light source module comprises steps of applying first solder (solder having a higher melting point) and second solder (solder having a lower melting point) onto a pair of metal plating layers of Au or the like formed on the upper surface of the silicon substrate, bonding a first light source chip to the silicon substrate with the first solder melted by applying heat of 300° C. in a state where the first light source chip is arranged on the first solder (solder having a higher melting point) and bonding a second light source chip to the silicon substrate with the second solder melted by applying heat of 200° C. in a state where the second light source chip is arranged on the second solder (solder having a lower melting point) having a lower melting point than the first solder after bonding the first light source chip to the silicon substrate. In this method of manufacturing the semiconductor light source module, not only the first solder (solder having a higher melting point) but also the second solder (solder having a lower melting point) employed in the later bonding step are melted when the first light source chip is bonded to the silicon substrate.

In the method of manufacturing the semiconductor light source module disclosed in Japanese Patent Laying-Open No. 2000-268387, however, not only the first solder but also the second solder employed in the later bonding step are melted when the first light source chip is bonded to the silicon substrate, and hence the melted second solder and the metal plating layer on a lower portion of the second solder may conceivably react and be alloyed with each other. Thus, a melting point of a metal layer after alloying may be rendered higher than a melting point of the metal layer before alloying if a composition of individual metal materials constituting the metal layer (alloy layer) made of at least two materials is changed due to alloying of the metal layer. In this case, the second solder must be heated at higher temperature and melted, and hence thermal stress generated in the second light source chip is disadvantageously increased due to excessive heating. Consequently, luminous characteristics of the second light source chip are disadvantageously decreased, or the life thereof is disadvantageously decreased.

### SUMMARY OF THE INVENTION

A method of manufacturing a semiconductor laser apparatus according to a first aspect of the present invention comprises steps of forming a first solder layer with a first melting point on a first electrode of a base formed with the first electrode and a second electrode on a surface thereof, forming a second solder layer with a second melting point on the second electrode of the base through a barrier layer, forming a reaction solder layer with a third melting point higher than the second melting point by melting the first solder layer with the first melting point to react the first electrode with the first solder layer, and bonding a first semiconductor laser device to the base through the reaction solder layer, and bonding a second semiconductor laser device to the base through the second solder layer by applying heat of a first heating temperature to melt the second solder layer with the second melting point lower than the third melting point after the step of bonding the first semiconductor laser device to the base.

A semiconductor laser apparatus according to a second aspect of the present invention comprises a base including a first electrode and a second electrode formed on a surface thereof, a reaction solder layer formed on the first electrode by reacting a first solder layer having a first melting point with the first electrode, a barrier layer formed on the second electrode and a second solder layer formed on the barrier layer, having a second melting point, a first semiconductor laser device bonded to the base through the reaction solder layer, and a second semiconductor laser device bonded to the base through the second solder layer, wherein a third melting point of the reaction solder layer is higher than the second melting point of the second solder layer.

An optical apparatus according to a third aspect of the present invention comprises the semiconductor laser apparatus in the first or second aspect and an optical system controlling a laser beam emitted from the semiconductor laser apparatus.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top plan view of a two-wavelength semiconductor laser apparatus according to a first embodiment of the present invention;

FIG. 2 is a front elevational view of the two-wavelength semiconductor laser apparatus according to the first embodiment of the present invention, as viewed from a laser beam emitting direction;

FIG. 3 is a phase diagram of an Au—Sn alloy for illustrating a composition of a solder layer (reaction solder layer) of the two-wavelength semiconductor laser apparatus according to the first embodiment of the present invention;

FIG. 4 is a graph for illustrating a manufacturing process of the two-wavelength semiconductor laser apparatus according to the first embodiment of the present invention;

FIG. 5 is a top plan view for illustrating the manufacturing process of the two-wavelength semiconductor laser apparatus according to the first embodiment of the present invention;

FIGS. 6 to 8 are sectional views for illustrating the manufacturing process of the two-wavelength semiconductor laser apparatus according to the first embodiment of the present invention;

FIG. 9 is a front elevational view of a three-wavelength semiconductor laser apparatus according to a second embodiment of the present invention, as viewed from a laser beam emitting direction;

FIGS. 10 to 12 are sectional views for illustrating a manufacturing process of the three-wavelength semiconductor laser apparatus according to the second embodiment of the present invention; and

FIG. 13 is a schematic diagram showing a structure of an optical pickup according to a third embodiment of the present invention.

### DESCRIPTION OF THE PREFERRED EMBODIMENTS

Embodiments of the present invention are hereinafter described with reference to the drawings.

(First Embodiment)

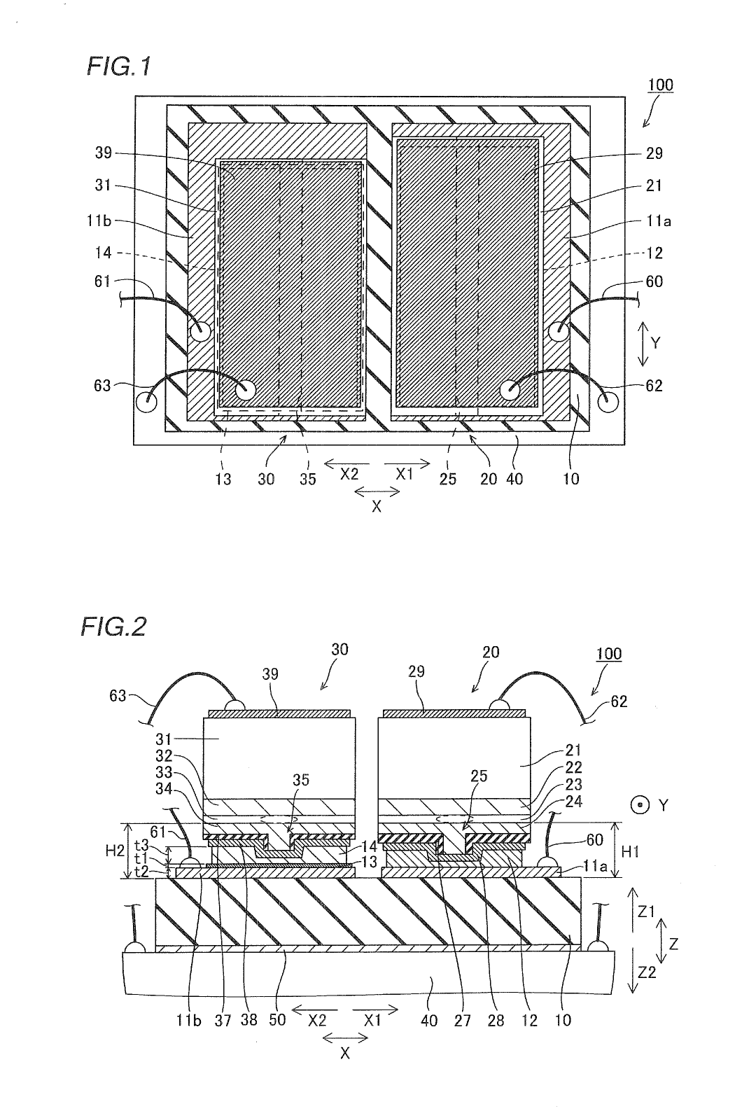

A structure of a two-wavelength semiconductor laser apparatus 100 according to a first embodiment of the present invention is now described with reference to FIGS. 1 to 6. The two-wavelength semiconductor laser apparatus 100 is an example of the “semiconductor laser apparatus” in the present invention.

The two-wavelength semiconductor laser apparatus 100 according to the first embodiment of the present invention comprises a flat heat radiation substrate 10 having a prescribed thickness, a red semiconductor laser device 20 having a lasing wavelength of about 650 nm and a blue-violet semiconductor laser device 30 having a lasing wavelength of about 405 nm both bonded to the heat radiation substrate 10, and a base portion 40 supporting the heat radiation substrate 10 from below (from a Z2 side), as shown in FIGS. 1 and 2. The heat radiation substrate 10 is bonded to the base portion 40 through a bonding layer 50 (see FIG. 2). The heat radiation substrate 10 is an example of the “base” in the present invention. The red semiconductor laser device 20 is an example of the “first semiconductor laser device” in the present invention, and the blue-violet semiconductor laser device 30 is an example of the “second semiconductor laser device” in the present invention.

As shown in FIG. 2, an electrode 11a formed on one side (X1 side) in a direction X orthogonal to an emitting direction (direction Y) of a laser beam and an electrode 11b formed on the other side (X2 side) in the direction X are formed on an upper surface (on a Z1 side) of the heat radiation substrate 10 to be adjacent to each other. The electrodes 11a and 11b are metal electrodes made of Au. The electrodes 11a and 11b are examples of the “first electrode” and the “second electrode” in the present invention, respectively.

The red semiconductor laser device 20 is bonded to the electrode 11a through a reaction solder layer 12 on an X1 side of the heat radiation substrate 10. The blue-violet semiconductor laser device 30 is bonded to the electrode 11b through a solder layer 14 on an X2 side of the heat radiation substrate 10.

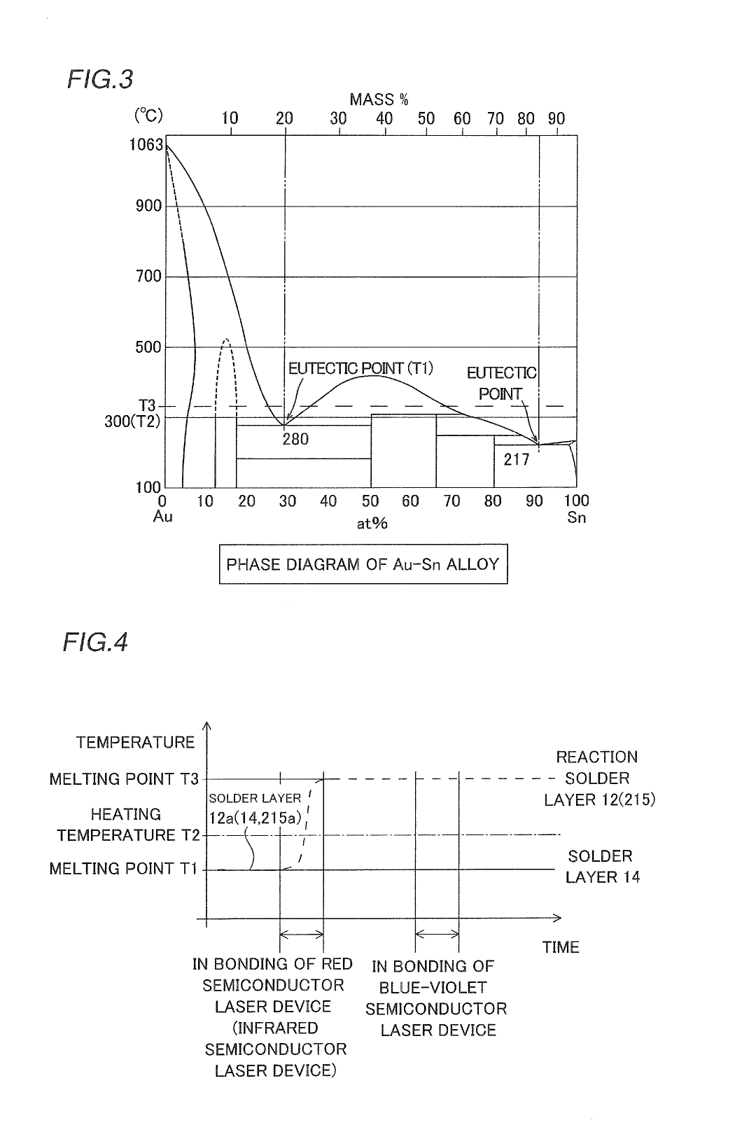

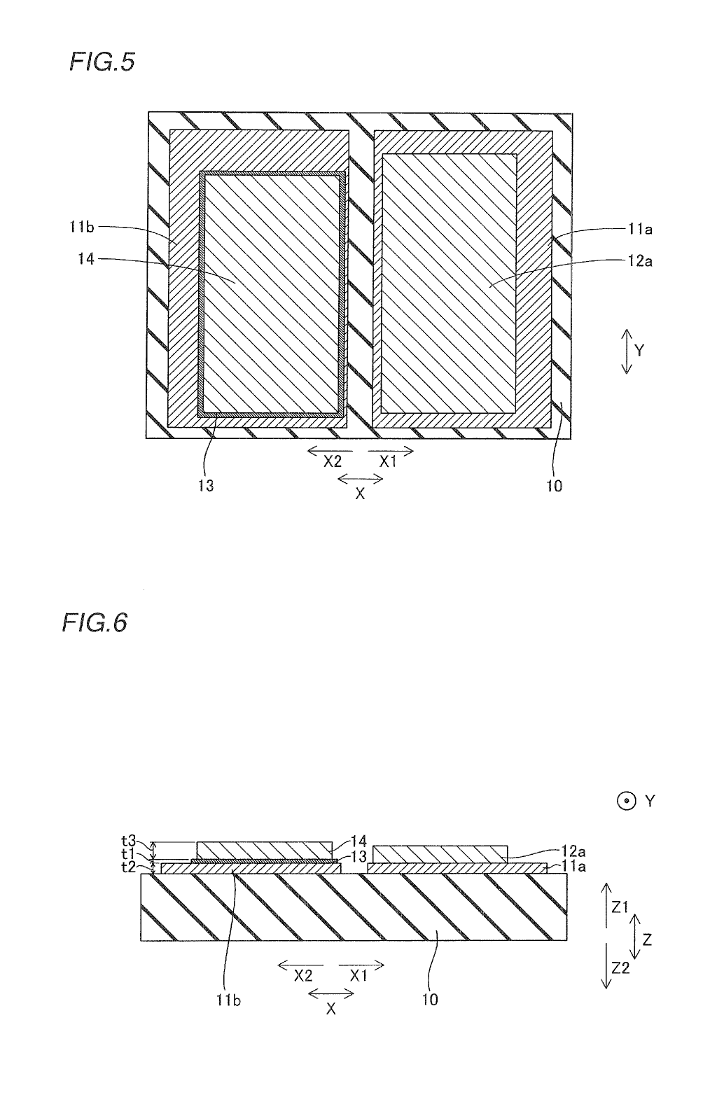

According to the first embodiment, the reaction solder layer 12 is made of an Au—Sn alloy containing Au, the content of which is larger than 80 mass %, and Sn, the content of which is smaller than 20 mass %. A solder layer 12a (see FIGS. 5 and 6) made of an Au—Sn alloy formed on the electrode 11a reacts (is alloyed) with Au contained in the electrode 11a before the red semiconductor laser device 20 is bonded to the heat radiation substrate 10, whereby this reaction solder layer 12 is formed. The solder layer 12a is made of an Au—Sn alloy containing about 80 mass % Au and about 20 mass % Sn and has a melting point T1 of about 280° C. On the other hand, a melting point T3 of the reaction solder layer 12 is higher than the melting point T1 of the solder layer 12a and a melting point at a eutectic point at which an Au—Sn alloy has a composition of about 80 mass % Au and about 20 mass % Sn, as shown in FIGS. 3 and 4. The solder layer 12a is an example of the “first solder layer” in the present invention. The melting point T1 of the solder layer 12a is an example of the “first melting point” in the present invention, and the melting point T3 of the reaction solder layer 12 is an example of the “third melting point” in the present invention.

The solder layer 14 is made of an Au—Sn alloy containing about 80 mass % Au and about 20 mass % Sn. The solder layer 14 is formed on a surface of the electrode 11b through a barrier layer 13 made of Pt formed on the surface of the electrode 11b on the heat radiation substrate 10. This barrier layer 13 has a function of inhibiting the diffusion of Au contained in the electrode 11b into the solder layer 14. The solder layer 14 is an example of the “second solder layer” in the present invention.

As shown in FIG. 1, the barrier layer 13 arranged on a lower side of the solder layer 14 is formed such that both end portions thereof in the directions X and Y, which are an outer edge of the barrier layer 13 and a portion around the outer edge, are exposed on regions outward beyond both end portions of the solder layer 14 in the directions X and Y, respectively. In other words, the barrier layer 13 is formed over at least a region formed with the solder layer 14 and formed with a plane area larger than that of the solder layer 14 on a lower portion of the solder layer 14. Thus, the barrier layer 13 is so formed that the electrode lib and the solder layer 14 are not in direct contact with each other.

According to the first embodiment, the solder layer 14 is made of an Au—Sn alloy having the same composition as the aforementioned solder layer 12a and has the same melting point T1 (about 280° C.) as the solder layer 12a. The solder layers 12a and 14 each have a composition substantially identical to a eutectic composition with a melting point of about 280° C. shown in FIG. 3. As shown in

FIG. 4, the melting point T1 of the solder layer 14 is lower than the melting point T3 of the reaction solder layer 12 having a larger content of Au than the solder layer 14. The melting point T1 of the solder layer 14 is an example of the “second melting point” in the present invention.

As shown in FIG. 2, a thickness t1 (in a direction Z) of the barrier layer 13 is smaller than a thickness t2 of the electrode lib and a thickness t3 of the solder layer 14.

The red semiconductor laser device 20 is formed with an n-type cladding layer 22 made of AlGaInP on a lower surface of an n-type GaAs substrate 21. An active layer 23 having a multiple quantum well (MQW) structure formed by alternately stacking quantum well layers (not shown) made of GaInP and barrier layers (not shown) made of AlGaInP is formed on a lower surface of the n-type cladding layer 22. A p-type cladding layer 24 made of AlGaInP is formed on a lower surface of the active layer 23. The active layer 23 is an example of the “first light-emitting layer” in the present invention.

A ridge portion (projecting portion) 25 extending along the direction Y, which is an emitting direction of a laser beam, is formed on the p-type cladding layer 24 in a substantially central portion of the red semiconductor laser device 20 in the direction X. A current blocking layer 27 made of SiO₂ is formed on a lower surface of the p-type cladding layer 24 other than the ridge portion 25 and both side surfaces of the ridge portion 25. A p-side electrode 28 made of Au or the like is formed on lower surfaces of the ridge portion 25 and the current blocking layer 27. This p-side electrode 28 is connected to the electrode 11a and a lead terminal (on an anode side) (not shown) through the reaction solder layer 12. An n-side electrode 29 in which an AuGe layer, an Ni layer and an Au layer are stacked successively from a side closer to the n-type GaAs substrate 21 is formed on a substantially entire region of an upper surface of the n-type GaAs substrate 21.

The red semiconductor laser device 20 is bonded onto the upper surface of the heat radiation substrate 10 such that the active layer 23 and the ridge portion 25 are located on a lower side of the n-type GaAs substrate 21 by bonding the p-side electrode 28 and the upper surface of the heat radiation substrate 10 onto each other. In other words, the red semiconductor laser device 20 is bonded to the heat radiation substrate 10 in a junction-down system. The red semiconductor laser device 20 is bonded to the heat radiation substrate 10 such that the active layer 23 thereof is located at a height H1 upward from (on a Z1 side of) the upper surface of the heat radiation substrate 10. The height H1 is an example of the “first distance” in the present invention.

The blue-violet semiconductor laser device 30 is formed with an n-type cladding layer 32 made of n-type AlGaN on a lower surface of an n-type GaN substrate 31. An active layer 33 having an MQW structure formed by alternately stacking quantum well layers (not shown) made of InGaN and barrier layers (not shown) made of GaN is formed on a lower surface of the n-type cladding layer 32. A p-type cladding layer 34 made of p-type AlGaN is formed on a lower surface of the active layer 33. The active layer 33 is an example of the “second light-emitting layer” in the present invention.

A ridge portion (projecting portion) 35 extending along the direction Y, which is an emitting direction of a laser beam, is formed on the p-type cladding layer 34 in a substantially central portion of the blue-violet semiconductor laser device 30 in the direction X. A current blocking layer 37 made of SiO₂ is formed on a lower surface of the p-type cladding layer 34 other than the ridge portion 35 and both side surfaces of the ridge portion 35. A p-side electrode 38 is formed on lower surfaces of the ridge portion 35 and the current blocking layer 37. This p-side electrode 38 is connected to the electrode lib and a lead terminal (on the anode side) (not shown) through the solder layer 14 and the barrier layer 13. An n-side electrode 39 in which an Al layer, a Pt layer and an Au layer are stacked successively from a side closer to the n-type GaN substrate 31 is formed on a substantially entire region of an upper surface of the n-type GaN substrate 31.

The blue-violet semiconductor laser device 30 is bonded onto the upper surface of the heat radiation substrate 10 such that the active layer 33 and the ridge portion 35 are located on a lower side of the n-type GaN substrate 31 by bonding the p-side electrode 38 and the upper surface of the heat radiation substrate 10 onto each other. In other words, the blue-violet semiconductor laser device 30 is bonded to the heat radiation substrate 10 in a junction-down system. The blue-violet semiconductor laser device 30 is bonded to the heat radiation substrate 10 such that the active layer 33 thereof is located at a height H2 upward from (on the Z1 side of) the upper surface of the heat radiation substrate 10. The height H2 is an example of the “second distance” in the present invention.

As shown in FIG. 2, a thickness (in the direction Z) of the current blocking layer 27 in the red semiconductor laser device 20 is larger than a thickness (in the direction Z) of the current blocking layer 37 in the blue- violet semiconductor laser device 30 by the thickness t1 of the barrier layer 13. Thus, the height H1 from the active layer 23 of the red semiconductor laser device 20 to the upper surface of the heat radiation substrate 10 and the height H2 from the active layer 33 of the blue-violet semiconductor laser device 30 to the upper surface of the heat radiation substrate 10 are substantially equal to each other. Thus, the active layer 23 of the red semiconductor laser device 20 and the active layer 33 of the blue-violet semiconductor laser device 30 are located at the heights substantially equal to each other.

The electrode 11a formed on the heat radiation substrate 10 and the lead terminal (on the anode side) (not shown) are electrically connected with each other through a wire 60. The electrode lib formed on the heat radiation substrate 10 and the lead terminal (on the anode side) (not shown) are electrically connected with each other through a wire 61. The n-side electrode 29 of the red semiconductor laser device 20 and the base portion 40 are electrically connected with each other through a wire 62. The n-side electrode 39 of the blue-violet semiconductor laser device 30 and the base portion 40 are electrically connected with each other through a wire 63. The base portion 40 is connected to a cathode terminal (not shown).

A manufacturing process of the two-wavelength semiconductor laser apparatus 100 according to the first embodiment is now described with reference to FIGS. 4 to 8. As shown in FIGS. 5 and 6, the electrodes 11a and 11b made of Au are first formed on the X1 and X2 sides, respectively, on the upper surface of the heat radiation substrate 10. Thereafter, the barrier layer 13 made of Pt is formed on the surface of the electrode 11b. At this time, the thickness t1 of the barrier layer 13 is smaller than the thickness t2 of the electrode 11b.

Thereafter, the solder layers 12a and 14 each formed of an Au—Sn alloy solder layer containing about 80 mass % Au and about 20 mass % Sn are formed on upper surfaces of the electrode 11a and the barrier layer 13, respectively. At this time, the solder layer 14 is formed such that the both end portions thereof in the directions X and Y are located inward beyond the both end portions of the barrier layer 13 in the directions X and Y (the outer edge of the barrier layer 13 and the portion around the outer edge). Further, the solder layer 14 is formed such that the thickness t3 thereof is larger than the thickness t1 of the barrier layer 13.

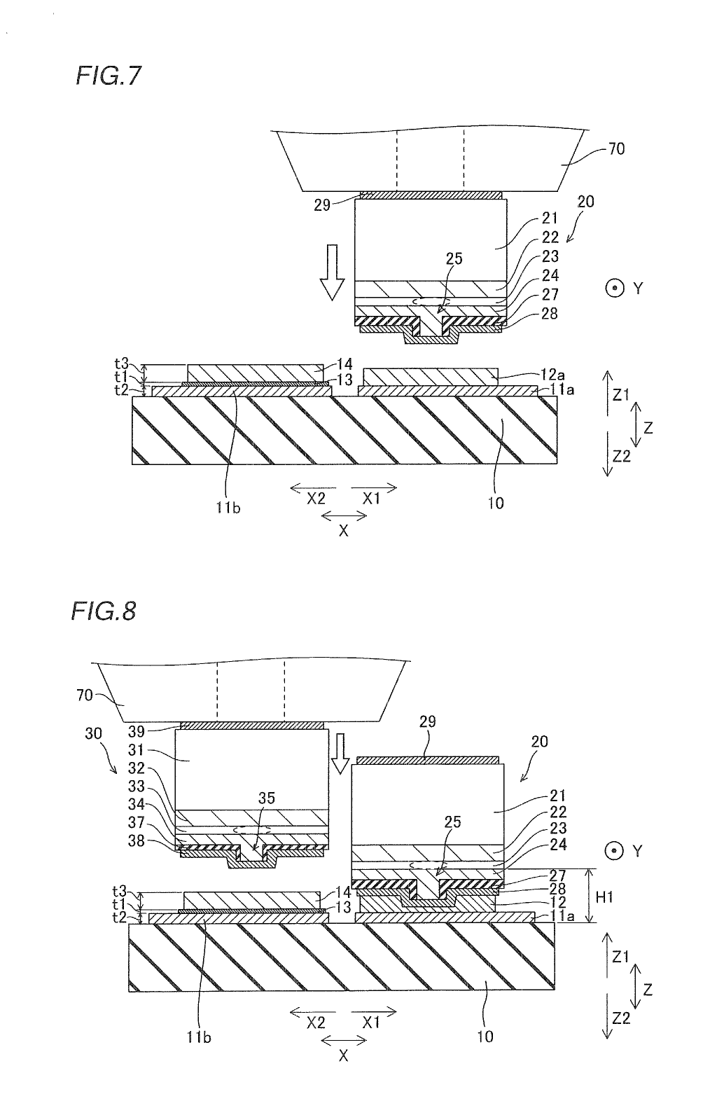

The red semiconductor laser device 20 (see FIG. 7) and the blue-violet semiconductor laser device 30 (see FIG. 8) are formed through prescribed manufacturing processes. At this time, the red semiconductor laser device 20 and the blue-violet semiconductor laser device 30 are formed such that the thickness (in the direction Z) of the current blocking layer 27 in the red semiconductor laser device 20 is larger than the thickness (in the direction Z) of the current blocking layer 37 of the blue-violet semiconductor laser device 30 by the thickness t1 of the barrier layer 13.

Thereafter, the n-side electrode 29 of the red semiconductor laser device 20 is grasped from above (from a Z1 side) with a collet 70 such that the p-side electrode 28 of the red semiconductor laser device 20 and the solder layer 12a are opposed to each other, as shown in FIG. 7. Then, the p-side electrode 28 of the red semiconductor laser device 20 and the electrode 11a are bonded to each other through the solder layer 12a. At this time, heat of a heating temperature T2 (about 300° C.) higher than the melting point T1 (about 280° C.) is applied to the solder layer 12a in the manufacturing process of the first embodiment. Thus, Au in the electrode 11a is diffused into the solder layer 12a and reacts with the Au—Sn alloy in the solder layer 12a, whereby the reaction solder layer 12 (see FIG. 8) in which the content of Au is relatively larger than 80 mass % is formed. Therefore, the melting point T3 of the solidified reaction solder layer 12 is rendered higher than the melting point T1 (about 280° C.) of the solder layer 12a before the solder layer 12a and the electrode 11a react (are alloyed) with each other, and is rendered higher than the heating temperature T2 (about 300° C.) for melting the solder layers 12a and 14, as shown in FIG. 4. The heating temperature T2 is an example of the “second heating temperature” in the present invention.

In the manufacturing process of the first embodiment, heat for melting the solder layer 12a is partially applied to the solder layer 14 near the solder layer 12a when the solder layer 12a is melted. However, the barrier layer 13 inhibits the reaction of the solder layer 14 with the electrode 11b located below the solder layer 14, and hence the composition (about 80 mass % Au and about 20 mass % Sn) of the solder layer 14 is substantially constant, and the melting point T1 of the solder layer 14 is substantially constant. In other words, the melting point of the solder layer 14 is kept to be T1 when the red semiconductor laser device 20 is bonded to the heat radiation substrate 10, as shown in FIG. 4.

The red semiconductor laser device 20 is bonded such that the active layer 23 thereof is located at the height H1 (see FIG. 8) upward from (on the Z1 side of) the upper surface of the heat radiation substrate 10. The red semiconductor laser device 20 is bonded onto the upper surface of the heat radiation substrate 10 in a junction-down system such that the active layer 23 and the ridge portion 25 are located below the n-type GaAs substrate 21. In a state where the reaction solder layer 12 having a melting point T3 is solidified, the n-side electrode 39 of the blue-violet semiconductor laser device 30 is grasped from above (from the Z1 side) with the collet 70 such that the p-side electrode 38 of the blue-violet semiconductor laser device 30 and the solder layer 14 are opposed to each other, as shown in FIG. 8. Then, the p-side electrode 38 of the blue-violet semiconductor laser device 30 and the electrode 11b are bonded to each other through the solder layer 14. At this time, heat of a heating temperature T2 (about 300° C.) higher than the melting point T1 (about 280° C.) and lower than the melting point T3 of the reaction solder layer 12 is applied to the solder layer 14 in the manufacturing process of the first embodiment. The heating temperature T2 is an example of the “first heating temperature” in the present invention.

The melting point T1 of the solder layer 14 is substantially constant when the red semiconductor laser device 20 is bonded to the heat radiation substrate 10 (the solder layer 12a is melted), and hence the solder layer 14 is melted at the heating temperature T2. On the other hand, the melting point T3 of the reaction solder layer 12 formed by the reaction (alloying) of the solder layer 12a with the electrode 11a is higher than the heating temperature T2 for melting the solder layer 14, as shown in FIG. 4, and hence the reaction solder layer 12 is hardly melted even if heat for melting the solder layer 14 is partially applied to the reaction solder layer 12 near the solder layer 14 when the solder layer 14 is melted. Thus, a bonding position of the red semiconductor laser device 20 previously bonded to the heat radiation substrate 10 does not deviate.

The blue-violet semiconductor laser device 30 is bonded such that the active layer 33 thereof is located at the height H2 (see FIG. 2) upward from (on the Z1 side of) the upper surface of the heat radiation substrate 10. The blue-violet semiconductor laser device 30 is bonded onto the upper surface of the heat radiation substrate 10 in a junction-down system such that the active layer 33 and the ridge portion 35 are located below the n-type GaN substrate 31.

Thereafter, the heat radiation substrate 10 is bonded to the base portion 40 through the bonding layer 50, as shown in FIG. 2. Then, the electrode 11a and the lead terminal (on the anode side) (not shown) are connected with each other through the wire 60, as shown in FIG. 1. The electrode 11b and the lead terminal (on the anode side) (not shown) are connected with each other through the wire 61. The n-side electrode 29 of the red semiconductor laser device 20 and the base portion 40 are connected with each other through the wire 62. The n-side electrode 39 of the blue-violet semiconductor laser device 30 and the base portion 40 are connected with each other through the wire 63. Thus, the two-wavelength semiconductor laser apparatus 100 is formed.

According to the first embodiment, as hereinabove described, the barrier layer 13 made of Pt is formed on the surface (Z1 side) of the electrode 11b on the heat radiation substrate 10, and the solder layer 14 is formed on the upper surface of the barrier layer 13, whereby the barrier layer 13 lies between the solder layer 14 and the electrode 11b thereby inhibiting direct contact between the solder layer 14 and the electrode 11b even if heat for melting the solder layer 12a with the melting point T1 is applied to the solder layer 14 when the red semiconductor laser device 20 is bonded to the heat radiation substrate 10. Thus, the melting point of the solder layer 14 can be inhibited from becoming higher than the melting point T1, dissimilarly to a case where heat is applied in a state where the solder layer 14 and the electrode 11b are in direct contact with each other thereby alloying the solder layer 14 and the electrode 11b with each other and increasing the melting point of the solder layer 14. Therefore, the blue-violet semiconductor laser device 30 can be bonded by melting the solder layer 14 without increasing the heating temperature T2 to a higher temperature when the blue-violet semiconductor laser device 30 is bonded to the heat radiation substrate 10 to which the red semiconductor laser device 20 has been bonded. Consequently, excessive heating is not required, and hence thermal stress generated in the blue-violet semiconductor laser device 30 can be inhibited from increase. Therefore, luminous characteristics of the blue-violet semiconductor laser device 30 and the life of the blue-violet semiconductor laser device 30 can be inhibited from decrease when the blue-violet semiconductor laser device 30 is bonded to the heat radiation substrate 10. Further, the barrier layer 13 made of Pt inhibits the diffusion of a material constituting the electrode 11b into the solder layer 14 when the red semiconductor laser device 20 and the blue-violet semiconductor laser device 30 are bonded to the heat radiation substrate 10, and hence the melting point T1 of the solder layer 14 can be reliably inhibited from increase.

According to the first embodiment, the heating temperature T2 (about 300° C.) for melting the solder layer 14 is set to be higher than the melting point T1 (about 280° C.) of the solder layer 14, whereby the solder layer 14 can be easily melted at the heating temperature T2 of at least the melting point T1.

According to the first embodiment, the heating temperature T2 (about 300° C.) is set to be less than the melting point T3 of the reaction solder layer 12, whereby even if heat for melting the solder layer 14 is applied to the reaction solder layer 12, the reaction solder layer 12 can be inhibited from being melted because the heating temperature T2 is less than the melting point T3. Thus, the red semiconductor laser device 20 bonded to the heat radiation substrate 10 through the reaction solder layer 12 can be inhibited from deviating from a prescribed bonding position due to the melted reaction solder layer 12.

According to the first embodiment, the solder layer 12a and the solder layer 14 are formed to have the same melting point T1, whereby the barrier layer 13 between the solder layer 14 and the electrode 11b can easily inhibit the melting point T1 of the solder layer 14 from increase even if the solder layer 14 is melted when the red semiconductor laser device 20 is bonded to the heat radiation substrate 10 by melting the solder layer 12a.

According to the first embodiment, the heating temperature T2 (about 300° C.) is lower than the melting point T3 of the reaction solder layer 12. The solder layer 12a is melted at about 280° C. employing the heating temperature T2 lower than the melting point T3 and the melted solder layer 12a and the electrode 11a react with each other, whereby the reaction solder layer 12 having the melting point T3 higher than the heating temperature T2 can be formed, and hence the reaction solder layer 12 can be easily formed employing a lower heating temperature.

According to the first embodiment, the heating temperature for bonding the red semiconductor laser device 20 to the heat radiation substrate 10 and the heating temperature for bonding the blue-violet semiconductor laser device 30 to the heat radiation substrate 10 are set to be substantially equal to each other (heating temperature T2). Thus, the blue-violet semiconductor laser device 30 can be bonded to the heat radiation substrate 10 without changing the heating temperature for bonding the red semiconductor laser device 20 to the heat radiation substrate 10. In other words, a change of the heating temperature is not required, and hence the manufacturing process of the two-wavelength semiconductor laser apparatus 100 can be simplified.

According to the first embodiment, the reaction solder layer 12 is solidified to have the melting point T3 in a step of bonding the red semiconductor laser device 20 to the heat radiation substrate 10, and thereafter the blue-violet semiconductor laser device 30 is bonded to the heat radiation substrate 10 by applying heat of the heating temperature T2. Thus, the blue-violet semiconductor laser device 30 can be bonded to the heat radiation substrate 10 in a state where the reaction solder layer 12 reliably has the melting point T3. Further, the blue-violet semiconductor laser device 30 is bonded in a state where the red semiconductor laser device 20 is reliably bonded to the heat radiation substrate 10 through the solidified reaction solder layer 12, and hence the red semiconductor laser device 20 and the blue-violet semiconductor laser device 30 can be reliably aligned.

According to the first embodiment, the electrodes 11a and 11b made of Au are formed on the X1 and X2 sides, respectively, on the upper surface of the heat radiation substrate 10, and the barrier layer 13 made of Pt is formed on the electrode 11b. Then, the solder layers 12a and 14 each formed of an Au—Sn alloy solder layer containing about 80 mass % Au and about 20 mass % Sn and having the melting point T1 (about 280° C.) lower than the melting point T3 of the reaction solder layer 12 are formed on the upper surfaces of the electrode 11a and the barrier layer 13, respectively. Thus, Au in the electrode 11a and the Au—Sn alloy in the solder layer 12a are alloyed with each other when the red semiconductor laser device 20 is bonded to the heat radiation substrate 10, and hence the melting point of the reaction solder layer 12 can be easily increased to the melting point T3 higher than the melting point T1 of the solder layer 14. On the other hand, the melting point T1 of the solder layer 14 is constant due to the barrier layer 13, and hence a difference between the melting point T3 of the reaction solder layer 12 and the melting point T1 of the solder layer 14 can be easily generated.

According to the first embodiment, the electrodes 11a and 11b contain Au, and hence the electrode 11b can be formed of a common electrode material with the electrode 11a. In other words, the electrodes 11a and 11b can be formed on the surface of the heat radiation substrate 10 in the same step, and hence the manufacturing process can be simplified.

According to the first embodiment, the solder layers 12a and 14 each are formed of the Au—Sn alloy solder layer containing about 80 mass % Au and about 20 mass % Sn, which is a composition substantially identical to the eutectic composition having a melting point of about 280° C., whereby a step of forming the solder layer 12a and a step of forming the solder layer 14 can be performed in a single step, and hence the manufacturing process of the two-wavelength semiconductor laser apparatus 100 can be further simplified. Further, the solder layers 12a and 14 each have a composition substantially identical to the eutectic composition (about 80 mass % Au and about 20 mass % Sn) having a melting point of about 280° C., whereby a melting point (about 280° C.) at the eutectic point is lower than melting points of other compositions of an Au—Sn alloy, and hence the melting point T1 of the solder layer 12a having a composition identical to the eutectic composition and the melting point T1 of the solder layer 14 can be rendered lower than the melting points of other compositions of an Au—Sn alloy. Thus, the heating temperatures T2 for melting the solder layers 12a and 14 can be set to be lower, and hence thermal stress generated in the red semiconductor laser device 20 and the blue-violet semiconductor laser device 30 can be inhibited from increase when the red semiconductor laser device 20 and the blue-violet semiconductor laser device 30 are bonded to the heat radiation substrate 10. Further, if the p-side electrode 28 is made of Au, not only Au in the solder layers 12a and 14 but also Au in the p-side electrode 28 are incorporated into the reaction solder layer 12, and hence the content of Au in the reaction solder layer 12 can be further increased. Thus, the melting point T3 of the reaction solder layer 12 can be rendered higher, and it is more effective.

According to the first embodiment, the melting points T1 of the solder layers 12a and 14 are temperatures equal or close to the eutectic point of about 280° C. that the Au—Sn alloy in which the content (about 80%) of Au is larger than the content (about 20%) of Sn has. Thus, a temperature difference between the melting point T3 of the reaction solder layer 12 formed by reacting the electrode 11a with the solder layer 12a and the melting point T1 of the solder layer 14 can be clarified by employing the eutectic point of about 280° C. that the Au—Sn alloy in which the content of Au is larger than the content of Sn has, as shown in FIG. 3.

According to the first embodiment, Au in the electrode 11a is diffused into the Au—Sn alloy of the solder layer 12a by the diffusion of Au in the electrode 11a into the solder layer 12a and the reaction (alloying) of Au in the electrode 11a with the Au—Sn alloy in the solder layer 12a, whereby the reaction solder layer 12 formed of the Au—Sn alloy reaction solder layer having the melting point T3 higher than the melting point T1 of the solder layer 12a can be easily formed in a position of the solder layer 12a.

According to the first embodiment, the solder layer 14 is formed on the surface of the barrier layer 13 inward beyond the outer edge of the barrier layer 13 formed on the electrode 11b. Thus, the solder layer 14 can be easily formed without contact with the electrode 11b. Therefore, the solder layer 14 melted at the heating temperature T2 can be easily inhibited from reacting with the electrode 11b also when the red semiconductor laser device 20 is bonded to the heat radiation substrate 10.

According to the first embodiment, the thickness t1 of the barrier layer 13 is smaller than the thickness t2 of the electrode 11b and the thickness t3 of the solder layer 14. Thus, increase of electric resistance between the electrode 11b and the solder layer 14 can be inhibited as much as possible by utilizing a barrier function of the barrier layer 13 blocking the electrode 11b and the solder layer 14 from each other.

According to the first embodiment, the blue-violet semiconductor laser device 30 is bonded to the heat radiation substrate 10 after the red semiconductor laser device 20 is bonded to the heat radiation substrate 10, whereby the red semiconductor laser device 20 and the blue-violet semiconductor laser device 30 can be more accurately bonded onto prescribed bonding positions on the heat radiation substrate 10 as compared with a case where the red semiconductor laser device 20 and the blue-violet semiconductor laser device 30 are bonded to the heat radiation substrate 10 simultaneously. In general, the blue-violet semiconductor laser device 30 made of a nitride-based semiconductor is more easily influenced by heat in bonding than the red semiconductor laser device 20 made of a GaAs-based semiconductor. Therefore, the number of times for heating the blue-violet semiconductor laser device 30 can be limited to one if the blue-violet semiconductor laser device 30 is bonded after the red semiconductor laser device 20 is previously bonded to the heat radiation substrate 10, and hence heat damage of the blue-violet semiconductor laser device 30 can be effectively inhibited. Further, the heating temperature T2 in bonding is lower than the melting point T3 of the reaction solder layer 12, and hence heat damage of the blue-violet semiconductor laser device 30 can be minimized. Consequently, luminous characteristics of the blue-violet semiconductor laser device 30 can be inhibited from deterioration.

(Second Embodiment)

A second embodiment is described with reference to FIGS. 3, 4 and 9 to 12. In a three-wavelength semiconductor laser apparatus 200 according to this second embodiment, a two-wavelength semiconductor laser device 280 having a red semiconductor laser device 220 and an infrared semiconductor laser device 290 monolithically formed on the same GaAs substrate 281 is employed in place of the red semiconductor laser device 20 of the first embodiment. In the figures, a structure similar to that of the two-wavelength semiconductor laser apparatus 100 according to the first embodiment is denoted by the same reference numerals. The three-wavelength semiconductor laser apparatus 200 is an example of the “semiconductor laser apparatus” in the present invention.

A structure of the three-wavelength semiconductor laser apparatus 200 according to the second embodiment of the present invention is now described with reference to FIGS. 3, 4 and 9 to 11.

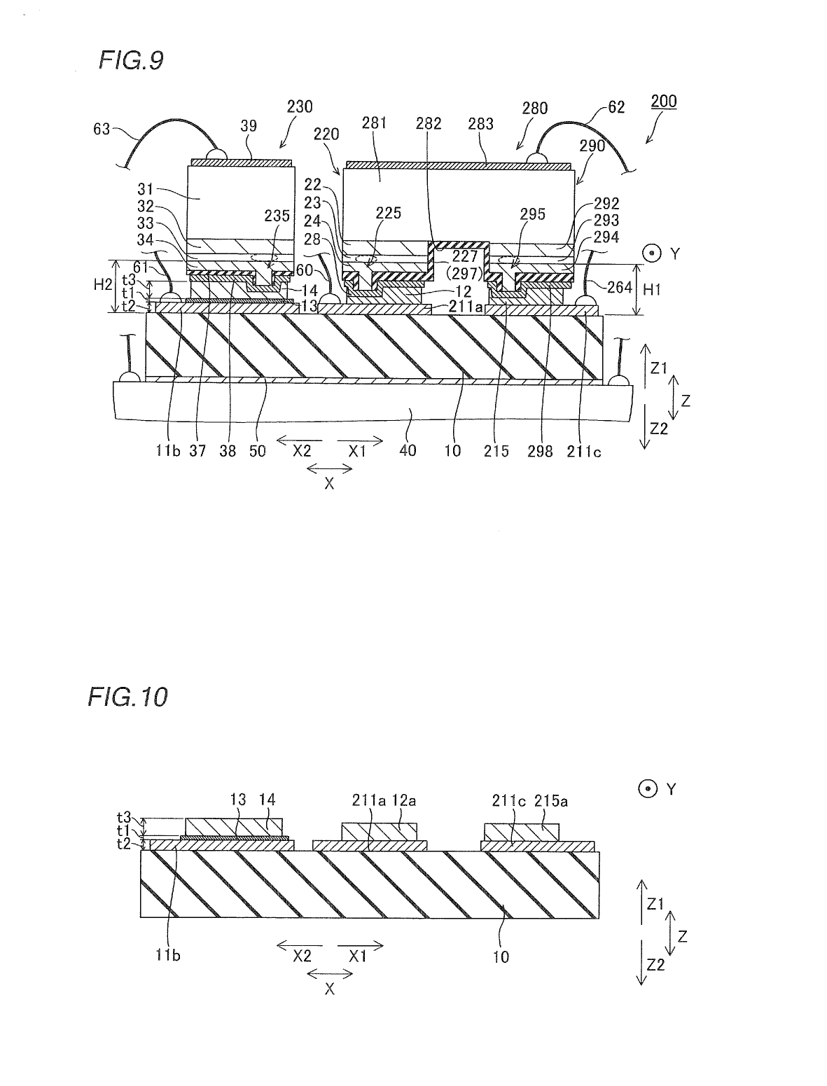

The three-wavelength semiconductor laser apparatus 200 according to the second embodiment comprises a heat radiation substrate 10, the two-wavelength semiconductor laser device 280 having the red semiconductor laser device 220 with a lasing wavelength of about 650 nm and the infrared semiconductor laser device 290 with a lasing wavelength of about 780 nm monolithically formed, a blue-violet semiconductor laser device 230 having a lasing wavelength of about 405 nm and a base portion 40, as shown in FIG. 9. The two-wavelength semiconductor laser device 280 is bonded onto an upper surface of the heat radiation substrate 10 on an X1 side, and the blue-violet semiconductor laser device 230 is bonded onto the upper surface of the heat radiation substrate 10 on an X2 side. The red semiconductor laser device 220 and the infrared semiconductor laser device 290 are an example of the “first semiconductor laser device” in the present invention. The blue-violet semiconductor laser device 230 is an example of the “second semiconductor laser device” in the present invention.

Electrodes 211c, 211a and 11b are formed on the upper surface of the heat radiation substrate 10 in this order from the X1 side to the X2 side. The electrodes 211a, 11b and 211c are metal electrodes made of Au. The red semiconductor laser device 220 of the two-wavelength semiconductor laser device 280 is bonded onto the electrode 211a through a reaction solder layer 12. The infrared semiconductor laser device 290 of the two-wavelength semiconductor laser device 280 is bonded onto the electrode 211c through a reaction solder layer 215. A barrier layer 13 is formed on the electrode 11b, and the blue-violet semiconductor laser device 230 is bonded onto the barrier layer 13 through a solder layer 14 in a junction-down system.

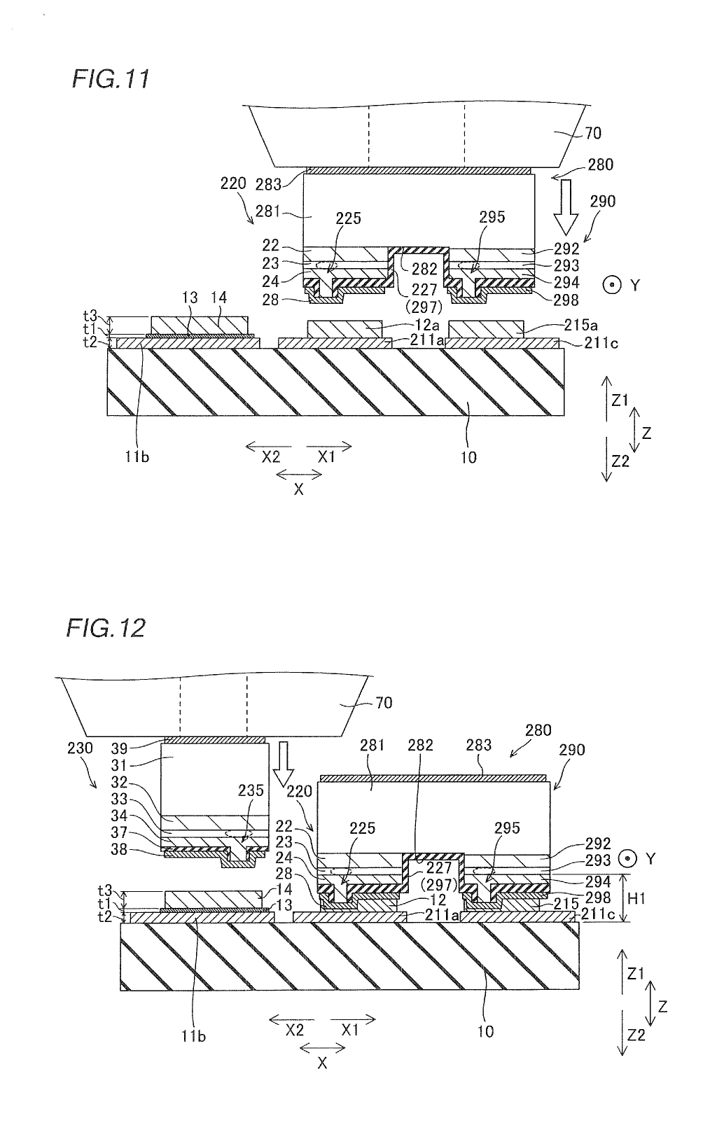

The reaction solder layer 215 on (on a Z1 side of) the electrode 211c is made of Au, the content of which is larger than 80 mass %, and Sn, the content of which is smaller than 20 mass %. A solder layer 215a (see FIGS. 10 and 11) made of an Au—Sn alloy formed on the electrode 211c reacts (is alloyed) with Au contained in the electrode 211c before the infrared semiconductor laser device 290 is bonded to the heat radiation substrate 10, whereby this reaction solder layer 215 is formed. The solder layer 215a has substantially the same composition (about 80 mass % Au and about 20 mass % Sn) as a solder layer 12a and has a melting point T1 (about 280° C.) substantially equal to a melting point of the solder layer 12a. On the other hand, the reaction solder layer 215 has substantially the same composition as the reaction solder layer 12 and has a melting point T3 substantially equal to a melting point of the reaction solder layer 12. The solder layer 215a is an example of the “first solder layer” in the present invention. The melting point T1 of the solder layer 215a is an example of the “first melting point” in the present invention, and the melting point T3 of the reaction solder layer 215 is an example of the “third melting point” in the present invention.

In the two-wavelength semiconductor laser device 280, the red semiconductor laser device 220 and the infrared semiconductor laser device 290 are monolithically formed on the common (same) n-type GaAs substrate 281. The red semiconductor laser device 220 is formed on the X2 side on a lower surface of the n-type GaAs substrate 281, and the infrared semiconductor laser device 290 is formed on the X1 side on the lower surface of the n-type GaAs substrate 281. The red semiconductor laser device 220 and the infrared semiconductor laser device 290 are separated from each other through a groove portion 282 formed in a substantially central portion of the lower surface of the n-type GaAs substrate 281 in a direction X.

The red semiconductor laser device 220 is formed with an n-type cladding layer 22, an active layer 23, a p-type cladding layer 24, a current blocking layer 227 and a p-side electrode 28 on the X2 side on the lower surface of the n-type GaAs substrate 281. A ridge portion 225 formed on the p-type cladding layer 24 of the red semiconductor laser device 220 is formed at a position deviating to the blue-violet semiconductor laser device 230 (X2 side) from a center of the red semiconductor laser device 220 in the direction X (horizontal direction). The current blocking layer 227 is formed integrally with a current blocking layer 297 of the infrared semiconductor laser device 290 described later.

The infrared semiconductor laser device 290 is formed with an n-type cladding layer 292 made of AlGaAs on the X1 side on the lower surface of the n-type GaAs substrate 281. An active layer 293 having an MQW structure formed by alternately stacking quantum well layers made of AlGaAs having a lower Al composition and barrier layers made of AlGaAs having a higher Al composition is formed on a lower surface of the n-type cladding layer 292. A p-type cladding layer 294 made of AlGaAs is formed on a lower surface of the active layer 293. The active layer 293 is an example of the “first light-emitting layer” in the present invention.

A ridge portion (projecting portion) 295 extending along a direction Y, which is an emitting direction of a laser beam, is formed on a portion of the p-type cladding layer 294 deviating to the blue-violet semiconductor laser device 230 (X2 side) from a center of the infrared semiconductor laser device 290 in the direction X (horizontal direction). The current blocking layer 297 formed integrally with the current blocking layer 227 of the red semiconductor laser device 220 is formed on a lower surface of the p-type cladding layer 294 other than the ridge portion 295 and both side surfaces of the ridge portion 295. A p-side electrode 298 made of Au or the like is formed on lower surfaces of the ridge portion 295 and the current blocking layer 297. This p-side electrode 298 is connected to the electrode 211c and a lead terminal (on an anode side) (not shown) through the reaction solder layer 215.

An n-side electrode 283 in which an AuGe layer, an Ni layer and an Au layer are stacked successively from a side closer to the n-type GaAs substrate 281 is formed on a substantially entire region of an upper surface of the n-type GaAs substrate 281.

The infrared semiconductor laser device 290 is bonded onto the upper surface of the heat radiation substrate 10 in a junction-down system such that the active layer 293 and the ridge portion 295 are located below the n-type GaAs substrate 281 by bonding the p-side electrode 298 and the upper surface of the heat radiation substrate 10 onto each other. The infrared semiconductor laser device 290 is bonded to the heat radiation substrate 10 such that the active layer 293 thereof is located at a height H1 upward from (on a Z1 side of) the upper surface of the heat radiation substrate 10.

A thickness (in a direction Z) of the current blocking layer 227 in the red semiconductor laser device 220 is larger than a thickness (in the direction Z) of a current blocking layer 37 in the blue-violet semiconductor laser device 230 by a thickness t1 of the barrier layer 13. A thickness of the current blocking layer 297 in the infrared semiconductor laser device 290 is larger than the thickness of the current blocking layer 37 in the blue-violet semiconductor laser device 230 by the thickness t1 of the barrier layer 13. Thus, a height H1 from the active layer 23 of the red semiconductor laser device 220 to the upper surface of the heat radiation substrate 10, the height H1 from the active layer 293 of the infrared semiconductor laser device 290 to the upper surface of the heat radiation substrate 10 and a height H2 from an active layer 33 of the blue-violet semiconductor laser device 230 to the upper surface of the heat radiation substrate 10 are substantially equal to each other. Thus, the active layer 23 of the red semiconductor laser device 220, the active layer 293 of the infrared semiconductor laser device 290 and the active layer 33 of the blue-violet semiconductor laser device 230 are located at the heights substantially equal to each other. A ridge portion 235 formed on a p-type cladding layer 34 of the blue-violet semiconductor laser device 230 is formed at a position deviating to the two-wavelength semiconductor laser device 280 (X1 side) from a center of the blue-violet semiconductor laser device 230 in the direction X (horizontal direction).

The electrode 211a formed on the heat radiation substrate 10 and a lead terminal (on the anode side) (not shown) are electrically connected with each other through a wire 60. The n-side electrode 283 of the two-wavelength semiconductor laser device 280 and the base portion 40 are electrically connected with each other through a wire 62. The electrode 211c formed on the heat radiation substrate 10 and the lead terminal (on the anode side) (not shown) are electrically connected with each other through a wire 264.

The remaining structure of the three-wavelength semiconductor laser apparatus 200 according to the second embodiment is similar to that of the two-wavelength semiconductor laser apparatus 100 according to the first embodiment.

A manufacturing process of the three-wavelength semiconductor laser apparatus 200 according to the second embodiment is now described with reference to FIGS. 4 and 9 to 12. As shown in FIG. 10, the electrodes 211c, 211a and 11b made of Au are first formed on the upper surface of the heat radiation substrate 10 in this order from the X1 side to the X2 side. Thereafter, the barrier layer 13 made of Pt is formed on the electrode 11b. Then, the solder layers 12a, 14 and 215a each formed of an Au—Sn alloy solder layer containing about 80 mass % Au and about 20 mass % Sn are formed on upper surfaces of the electrodes 211a, 11b and 211c, respectively.

The red semiconductor laser device 220 in which the ridge portion 225 deviates to a side (X2 side) farther from the infrared semiconductor laser device 290 from the center in the direction X (horizontal direction) and the infrared semiconductor laser device 290 (see FIG. 11) in which the ridge portion 295 deviates to the red semiconductor laser device 220 (X2 side) from the center in the direction X (horizontal direction) are monolithically formed on the same (common) n-type GaAs substrate 281 through prescribed manufacturing processes. The red semiconductor laser device 220 and the infrared semiconductor laser device 290 are formed such that the thickness of the current blocking layer 227 in the red semiconductor laser device 220 and the thickness of the current blocking layer 297 in the infrared semiconductor laser device 290 each are larger than the thickness of the current blocking layer 37 in the blue-violet semiconductor laser device 230 by the thickness t1 of the barrier layer 13. Thus, the two-wavelength semiconductor laser device 280 is formed. The blue-violet semiconductor laser device 230 (see FIG. 12) in which the ridge portion 235 deviates to one side from the center in the direction X (horizontal direction) is formed through a prescribed manufacturing process.

Thereafter, the n-side electrode 283 of the two-wavelength semiconductor laser device 280 is grasped from above (from a Z1 side) with a collet 70 such that the p-side electrode 28 of the red semiconductor laser device 220 and the solder layer 12a are opposed to each other while the p-side electrode 298 of the infrared semiconductor laser device 290 and the solder layer 215a are opposed to each other, as shown in FIG. 11. Then, the p-side electrode 28 of the red semiconductor laser device 220 and the electrode 211a are bonded to each other through the solder layer 12a. Similarly, the p-side electrode 298 of the infrared semiconductor laser device 290 and the electrode 211c are bonded to each other through the solder layer 215a. At this time, heat of a heating temperature T2 (about 300° C.) higher than the melting points T1 (about 280° C.) of the solder layers 12a and 215a is applied to each of the solder layers 12a and 215a in the manufacturing process of the second embodiment.

Thus, Au in the electrode 211a is diffused into the solder layer 12a and reacts with the Au—Sn alloy in the solder layer 12a, whereby the reaction solder layer 12 (see FIG. 12) in which the content of Au is relatively larger than 80 mass % is formed. Similarly, Au in the electrode 211c is diffused into the solder layer 215a and reacts with the Au—Sn alloy in the solder layer 215a, whereby the reaction solder layer 215 (see FIG. 12) in which the content of Au is relatively larger than 80 mass % is formed. Therefore, the melting points T3 of the reaction solder layers 12 and 215 are rendered higher than the melting point T1 (about 280° C.) of the solder layer 12a and are rendered higher than the heating temperature T2 (about 300° C.), as shown in FIG. 4. In the manufacturing process of the second embodiment, heat for melting the solder layers 12a and 215a is partially applied to the solder layer 14 when the solder layers 12a and 215a are melted. However, the barrier layer 13 inhibits the reaction of the solder layer 14 with the electrode 11b located below the solder layer 14, and hence the composition (about 80 mass % Au and about 20 mass % Sn) of the solder layer 14 is substantially constant, and the melting point T1 of the solder layer 14 is substantially constant.

The red semiconductor laser device 220 and the infrared semiconductor laser device 290 are bonded such that the active layer 23 of the red semiconductor laser device 220 and the active layer 293 of the infrared semiconductor laser device 290 are located at the heights H1 (see FIG. 12) upward from (on a Z1 side of) the upper surface of the heat radiation substrate 10. The red semiconductor laser device 220 and the infrared semiconductor laser device 290 are bonded onto the upper surface of the heat radiation substrate 10 in a junction-down system such that the ridge portions 225 and 295 are located below the GaAs substrate 281 and deviate to the blue-violet semiconductor laser device 230 (X2 side) from the centers of the red semiconductor laser device 220 and the infrared semiconductor laser device 290 in the direction X (horizontal direction).

Thereafter, the blue-violet semiconductor laser device 230 is bonded onto the upper surface of the heat radiation substrate 10 through the solder layer 14 melted by applying heat of the heating temperature T2 (about 300° C.), as shown in FIG. 12. The blue-violet semiconductor laser device 230 is bonded onto the upper surface of the heat radiation substrate 10 in a junction-down system such that the ridge portion 235 is located below an n-type GaN substrate 31 and deviates to the two-wavelength semiconductor laser device 280 (X1 side) from the center of the blue-violet semiconductor laser device 230 in the direction X (horizontal direction). The blue-violet semiconductor laser device 230 is bonded onto the upper surface of the heat radiation substrate 10 such that the height from the upper surface of the heat radiation substrate 10 to the active layer 33 of the blue-violet semiconductor laser device 230 in a vertical direction (direction Z) is H2 (see FIG. 9).

Thereafter, the heat radiation substrate 10 is bonded to the base portion 40 through a bonding layer 50, as shown in FIG. 9. Then, the electrode 211a and the lead terminal (on the anode side) (not shown) are connected with each other through the wire 60. The electrode 11b and a lead terminal (on the anode side) (not shown) are connected with each other through a wire 61. The n-side electrode 283 and the base portion 40 are connected with each other through the wire 62. An n-side electrode 39 and the base portion 40 are connected with each other through a wire 63. The electrode 211c and the lead terminal (on the anode side) (not shown) are connected with each other through the wire 264. Thus, the three-wavelength semiconductor laser apparatus 200 is formed.

The remaining manufacturing process of the three-wavelength semiconductor laser apparatus 200 according to the second embodiment is similar to that of the two-wavelength semiconductor laser apparatus 100 according to the first embodiment.

According to the second embodiment, as hereinabove described, the barrier layer 13 made of Pt is formed on the surface (Z1 side) of the electrode 11b on the heat radiation substrate 10, and the solder layer 14 is formed on an upper surface of the barrier layer 13 in a case where the three-wavelength semiconductor laser apparatus 200 comprises the two-wavelength semiconductor laser device 280 having the red semiconductor laser device 220 and the infrared semiconductor laser device 290 monolithically formed and the blue-violet semiconductor laser device 230. Thus, the barrier layer 13 lies between the solder layer 14 and the electrode lib thereby inhibiting direct contact between the solder layer 14 and the electrode lib even if heat for melting the solder layers 12a and 215a with the melting point T1 is applied to the solder layer 14 when the red semiconductor laser device 220 and the infrared semiconductor laser device 290 are bonded to the heat radiation substrate 10. Thus, the melting point of the solder layer 14 can be inhibited from becoming higher than the melting point T1, dissimilarly to a case where heat is applied in a state where the solder layer 14 and the electrode lib are in direct contact with each other thereby alloying the solder layer 14 and the electrode lib with each other and increasing the melting point of the solder layer 14. Consequently, the blue-violet semiconductor laser device 230 can be bonded by melting the solder layer 14 without increasing the heating temperature T2 to a higher temperature when the blue-violet semiconductor laser device 230 is bonded to the heat radiation substrate 10 to which the red semiconductor laser device 220 and the infrared semiconductor laser device 290 has been bonded. The remaining effects of the second embodiment are similar to those of the first embodiment.

(Third Embodiment)

An optical pickup 300 according to a third embodiment of the present invention is now described with reference to FIGS. 4, 9, 10 and 13. The optical pickup 300 is an example of the “optical apparatus” in the present invention.

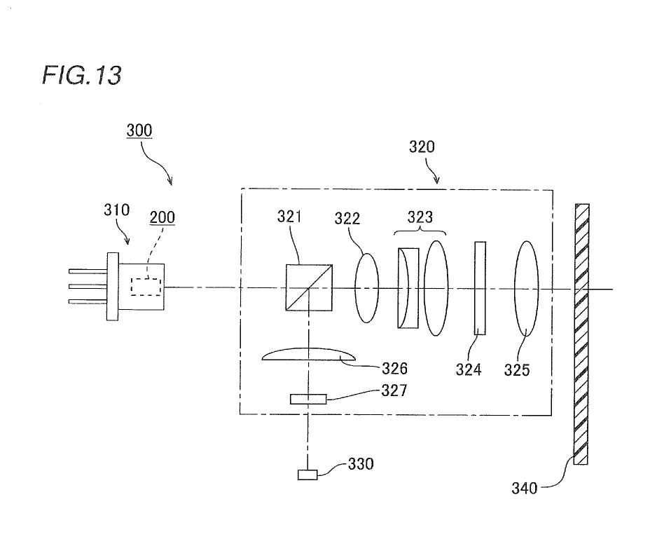

The optical pickup 300 according to the third embodiment of the present invention comprises a can-type three-wavelength semiconductor laser apparatus 310 mounted with the three-wavelength semiconductor laser apparatus 200 (see FIG. 9) according to the second embodiment, an optical system 320 adjusting laser beams emitted from the three-wavelength semiconductor laser apparatus 310 and a light detection portion 330 receiving the laser beams, as shown in FIG. 13.

The optical system 320 has a polarizing beam splitter (PBS) 321, a collimator lens 322, a beam expander 323, a λ/4 plate 324, an objective lens 325, a cylindrical lens 326 and an optical axis correction device 327.

The PBS 321 totally transmits the laser beams emitted from the three-wavelength semiconductor laser apparatus 310, and totally reflects the laser beams fed back from an optical disc 340. The collimator lens 322 converts the laser beams emitted from the three-wavelength semiconductor laser apparatus 310 and transmitted through the PBS 321 to parallel beams. The beam expander 323 is constituted by a concave lens, a convex lens and an actuator (not shown). The actuator has a function of correcting wave surface states of the laser beams emitted from the three-wavelength semiconductor laser apparatus 310 by varying a distance between the concave lens and the convex lens.

The λ/4 plate 324 converts the linearly polarized laser beams, substantially converted to the parallel beams by the collimator lens 322, to circularly polarized beams. Further, the λ/4 plate 324 converts the circularly polarized laser beams fed back from the optical disc 340 to linearly polarized beams. A direction of linear polarization in this case is orthogonal to a direction of linear polarization of the laser beams emitted from the three-wavelength semiconductor laser apparatus 310. Thus, the PBS 321 substantially totally reflects the laser beams fed back from the optical disc 340. The objective lens 325 converges the laser beams transmitted through the λ/4 plate 324 on a surface (recording layer) of the optical disc 340. An objective lens actuator (not shown) renders the objective lens 325 movable.

The cylindrical lens 326, the optical axis correction device 327 and the light detection portion 330 are arranged to be along optical axes of the laser beams totally reflected by the PBS 321. The cylindrical lens 326 provides the incident laser beams with astigmatic action. The optical axis correction device 327 is constituted by a diffraction grating and so arranged that spots of zero-order diffracted beams of blue-violet, red and infrared laser beams transmitted through the cylindrical lens 326 coincide with each other on a detection region of the light detection portion 330 described later.

The light detection portion 330 outputs a playback signal on the basis of intensity distribution of the received laser beams. Thus, the optical pickup 300 comprising the three-wavelength semiconductor laser apparatus 310 is formed.

In this optical pickup 300, the three-wavelength semiconductor laser apparatus 310 can independently emit red, blue-violet and infrared laser beams from the red semiconductor laser device 220, the blue-violet semiconductor laser device 230 and the infrared semiconductor laser device 290 (see FIG. 9). The laser beams emitted from the three-wavelength semiconductor laser apparatus 310 are adjusted by the PBS 321, the collimator lens 322, the beam expander 323, the λ/4 plate 324, the objective lens 325, the cylindrical lens 326 and the optical axis correction device 327 as described above, and thereafter applied onto the detection region of the light detection portion 330.

When data recorded in the optical disc 340 is play backed, the laser beams emitted from the red semiconductor laser device 220, the blue-violet semiconductor laser device 230 and the infrared semiconductor laser device 290 are controlled to have constant power and applied to the recording layer of the optical disc 340, so that the playback signal outputted from the light detection portion 330 can be obtained. When data is recorded in the optical disc 340, the laser beams emitted from the red semiconductor laser device 220 (infrared semiconductor laser device 290) and the blue-violet semiconductor laser device 230 are controlled in power and applied to the optical disc 340, on the basis of the data to be recorded. Thus, the data can be recorded in the recording layer of the optical disc 340. Thus, the data can be recorded in or played back from the optical disc 340 with the optical pickup 300 comprising the three-wavelength semiconductor laser apparatus 310.

According to the third embodiment, as hereinabove described, the barrier layer 13 (see FIG. 9) made of Pt is formed on the surface of the electrode 11b (see FIG. 9) on the heat radiation substrate 10 (see FIG. 9) of the three-wavelength semiconductor laser apparatus 200, and the solder layer 14 (see FIG. 9) is formed on the upper surface of the barrier layer 13 in a case where the optical pickup 300 comprises the three-wavelength semiconductor laser apparatus 310 mounted with the aforementioned three-wavelength semiconductor laser apparatus 200 according to the second embodiment. Thus, the barrier layer 13 lies between the solder layer 14 and the electrode lib thereby inhibiting direct contact between the solder layer 14 and the electrode lib even if heat for melting the solder layers 12a and 215a (see FIG. 10) with the melting point T1 (see FIG. 4) is applied to the solder layer 14 when the red semiconductor laser device 220 and the infrared semiconductor laser device 290 are bonded to the heat radiation substrate 10. Thus, the melting point of the solder layer 14 can be inhibited from becoming higher than the melting point T1, dissimilarly to a case where heat is applied in a state where the solder layer 14 and the electrode 11b are in direct contact with each other thereby alloying the solder layer 14 and the electrode 11b with each other and increasing the melting point of the solder layer 14. Consequently, the blue-violet semiconductor laser device 230 can be bonded by melting the solder layer 14 without increasing the heating temperature T2 to a higher temperature when the blue-violet semiconductor laser device 230 is bonded to the heat radiation substrate 10 to which the red semiconductor laser device 220 and the infrared semiconductor laser device 290 has been bonded.

According to the third embodiment, the three-wavelength semiconductor laser apparatus 200 according to the second embodiment is formed such that the height H1 from the active layer 23 (see FIG. 9) of the red semiconductor laser device 220 to the upper surface of the heat radiation substrate 10, the height H1 from the active layer 293 (see FIG. 9) of the infrared semiconductor laser device 290 to the upper surface of the heat radiation substrate 10 and the height H2 from the active layer 33 of the blue-violet semiconductor laser device 230 to the upper surface of the heat radiation substrate 10 are substantially equal to each other by adjusting the thickness of the current blocking layer 227 (see FIG. 9) of the red semiconductor laser device 220 and the thickness of the current blocking layer 297 (see FIG. 9) of the infrared semiconductor laser device 290. Thus, in the three-wavelength semiconductor laser apparatus 200 (310) formed with the barrier layer 13 only on a side of the blue-violet semiconductor laser device 230, the active layer 23 of the red semiconductor laser device 220, the active layer 293 of the infrared semiconductor laser device 290 and the active layer 33 of the blue-violet semiconductor laser device 230 can be located at the heights substantially equal to each other. Consequently, in the optical pickup 300, deviation in a height direction between an application position of a laser beam from the red semiconductor laser device 220, an application position of a laser beam from the infrared semiconductor laser device 290 and an application position of a laser beam from the blue-violet semiconductor laser device 230 can be inhibited from increase.

Although the present invention has been described and illustrated in detail, it is clearly understood that the same is by way of illustration and example only and is not to be taken by way of limitation, the spirit and scope of the present invention being limited only by the terms of the appended claims.

For example, while the barrier layer 13 is formed on the heat radiation substrate 10 (the electrode 11b) on a side where the blue-violet semiconductor laser device 30 or 230 is bonded in the aforementioned first and second embodiments, the present invention is not restricted to this. In the present invention, the barrier layer may be formed on the heat radiation substrate 10 (the electrode 11a or the electrodes 211a and 211c) on a side where the red semiconductor laser device 20 or 220 and the infrared semiconductor laser device 290 are bonded, and the barrier layer may not be formed on the heat radiation substrate 10 (the electrode 11b) on the side where the blue-violet semiconductor laser device 30 or 230 is bonded. In this case, the red semiconductor laser device and the infrared semiconductor laser device are bonded onto the heat radiation substrate after the blue-violet semiconductor laser device is bonded onto the heat radiation substrate.

While the solder layers 12a and 215a on a side where the barrier layer is not provided and the solder layer 14 on a side where the barrier layer 13 is provided are formed of the Au—Sn alloy solder layers having substantially the same composition (about 80 mass % Au and about 20 mass % Sn) in the aforementioned first and second embodiments, the present invention is not restricted to this. In the present invention, the “first solder layer” in the present invention on the side where the barrier layer is not provided and the “second solder layer” in the present invention on the side where the barrier layer is provided may be formed of Au—Sn alloy solder layers having different compositions from each other. At this time, the first melting point of the first solder layer on the side where the barrier layer is not provided is preferably lower than the third melting point of the reaction solder layer.

While the electrodes 11a, 211a and 211c and the electrode lib are made of Au, and the solder layers 12a and 215a, the solder layer 14 and the reaction solder layers 12 and 215 are made of an Au—Sn alloy in the aforementioned first and second embodiments, the present invention is not restricted to this. In the present invention, the electrodes may be made of metal other than Au, and the first solder layer, the second solder layer and the reaction solder layer may be made of a solder material other than an Au—Sn alloy as long as the reaction solder layer having the third melting point higher than the second melting point of the second solder layer is formed by reacting the first electrode with the first solder layer.

While the solder layers 12a, 212a and 215a and the solder layer 14 each are formed to have a composition substantially identical to the eutectic composition (about 80 mass % Au and about 20 mass % Sn) having a melting point of about 280° C. in the aforementioned first and second embodiments, the present invention is not restricted to this. In the present invention, the first solder layer and the second solder layer each may be formed to have a composition substantially identical to a eutectic composition (about 16 mass % Au and about 84 mass % Sn (see FIG. 3)) of an Au—Sn alloy having a melting point of about 217° C. Thus, the first melting point of the first solder layer and the second melting point of the second solder layer can be further decreased. However, the compositions of the first solder layer and the second solder layer are preferably substantially identical to the eutectic composition (about 80 mass % Au and about 20 mass % Sn) having a melting point of about 280° C. in which the amount of rise in the melting point to the amount of change in the content of Au is large in order to more easily generate a difference between the first melting point of the first solder layer and the third melting point of the reaction solder layer.

While the barrier layer 13 is made of Pt in each of the aforementioned first and second embodiments, the present invention is not restricted to this. In the present invention, the barrier layer may be made of Ti. Alternatively, the barrier layer may be made of a conductive material such as W, Mo or Hf other than Pt or Ti, or may be made of at least two of Pt, Ti, W, Mo and Hf.

While the two-wavelength semiconductor laser apparatus 100 includes the red semiconductor laser device 20 and the blue-violet semiconductor laser device 30 in the aforementioned first embodiment, and the three-wavelength semiconductor laser apparatus 200 includes the two-wavelength semiconductor laser device 280 having the red semiconductor laser device 220 and the infrared semiconductor laser device 290 monolithically formed and the blue-violet semiconductor laser device 230 in the aforementioned second embodiment, the present invention is not restricted to this. In the present invention, a green semiconductor laser device or a blue semiconductor laser device made of a nitride-based semiconductor may be employed in place of the blue-violet semiconductor laser device in each of the aforementioned first and second embodiments. An infrared semiconductor laser device may be employed in place of the red semiconductor laser device in the aforementioned first embodiment. The three-wavelength semiconductor laser apparatus of the aforementioned second embodiment may include the red semiconductor laser device, a green semiconductor laser device and a blue semiconductor laser device. Thus, the three-wavelength semiconductor laser apparatus having three primary colors of RGB can be formed.

While the blue-violet semiconductor laser devices 30 and 230, the red semiconductor laser devices 20 and 220 and the infrared semiconductor laser device 290 are bonded onto the heat radiation substrate 10 in a junction-down system such that the active layers and the ridge portions are located below the substrates in the aforementioned first and second embodiments, the present invention is not restricted to this. In the present invention, the blue-violet semiconductor laser device, the red semiconductor laser device and the infrared semiconductor laser device may be bonded onto the heat radiation substrate in a junction-up system such that the active layers and the ridge portions are located above the substrates.

While the thicknesses of the current blocking layers of the semiconductor laser devices on the side where the barrier layer is not provided are larger than the thickness of the current blocking layer of the semiconductor laser device on the side where the barrier layer is provided by the thickness of the barrier layer, whereby the active layers of the semiconductor laser devices on the side where the barrier layer is not provided and the active layer of the semiconductor laser device on the side where the barrier layer is provided are located at the heights substantially equal to each other in the aforementioned first and second embodiments, the present invention is not restricted to this. The active layers of the semiconductor laser devices may be located at the heights equal to each other or close to each other by adjusting thicknesses of the p-side pad electrode and the like arranged between the semiconductor laser devices on the side where the barrier layer is not provided and the upper surface of the heat radiation substrate, for example. Alternatively, the active layers of the semiconductor laser devices may be located at the heights equal to each other or close to each other by adjusting a thickness of a layer located between the semiconductor laser device on the side where the barrier layer is provided and the upper surface of the heat radiation substrate.

While the current blocking layers 27, 37, 227 and 297 are made of SiO₂ in the aforementioned first and second embodiments, the present invention is not restricted to this. Another insulating material such as SiN or a semiconductor material such as AlInP or AlGaN may be employed as the current blocking layers, for example.

While the aforementioned three-wavelength semiconductor laser apparatus 200 according to the second embodiment is mounted on the can-type three-wavelength semiconductor apparatus 310 in the aforementioned third embodiment, the present invention is not restricted to this. In the present invention, the aforementioned three-wavelength semiconductor laser apparatus 200 according to the second embodiment may be mounted on a frame-type three-wavelength semiconductor laser apparatus having a plate-like planar structure.

What is claimed is:

1. A method of manufacturing a semiconductor laser apparatus comprising steps of:
forming a first solder layer with a first melting point on a first electrode of a base formed with said first electrode and a second electrode on a surface thereof;
forming a second solder layer with a second melting point on said second electrode of said base through a barrier layer;
forming a reaction solder layer with a third melting point higher than said second melting point by melting said first solder layer with said first melting point to react said first electrode with said first solder layer, and bonding a first semiconductor laser device to said base through said reaction solder layer; and
bonding a second semiconductor laser device to said base through said second solder layer by applying heat of a first heating temperature to melt said second solder layer with said second melting point lower than said third melting point after said step of bonding said first semiconductor laser device to said base.

2. The method of manufacturing a semiconductor laser apparatus according to claim 1, wherein
said first heating temperature is at least said second melting point and less than said third melting point.

3. The method of manufacturing a semiconductor laser apparatus according to claim 1, wherein
said first melting point of said first solder layer is equal or close to said second melting point of said second solder layer and lower than said third melting point of said reaction solder layer.

4. The method of manufacturing a semiconductor laser apparatus according to claim 1, wherein
said step of bonding said first semiconductor laser device to said base includes a step of forming said reaction solder layer with said third melting point by melting said first solder layer with said first melting point at a second heating temperature to react said first electrode with said first solder layer, and bonding said first semiconductor laser device to said base through said reaction solder layer, and
said second heating temperature is lower than said third melting point of said reaction solder layer.

5. The method of manufacturing a semiconductor laser apparatus according to claim 4, wherein
said first heating temperature is substantially equal to said second heating temperature.

6. The method of manufacturing a semiconductor laser apparatus according to claim 1, wherein
said step of bonding said second semiconductor laser device to said base includes a step of bonding said second semiconductor laser device to said base by applying heat of said first heating temperature after said reaction solder layer is solidified to have said third melting point in said step of bonding said first semiconductor laser device to said base.

7. The method of manufacturing a semiconductor laser apparatus according to claim 1, wherein
at least said first electrode contains Au,
said first solder layer having said first melting point and said second solder layer having said second melting point each are formed of an Au—Sn alloy solder layer containing Au and Sn, and
said step of bonding said first semiconductor laser device to said base includes a step of forming said reaction solder layer with said third melting point higher than said second melting point by reacting said Au in said first electrode with said Au—Sn alloy solder layer of said first solder layer.

8. The method of manufacturing a semiconductor laser apparatus according to claim 7, wherein
said first electrode and said second electrode contain Au.

9. The method of manufacturing a semiconductor laser apparatus according to claim 7, wherein
said first solder layer and said second solder layer each are formed of said Au—Sn alloy solder layer having the same composition as or a similar composition to an Au—Sn alloy at a eutectic point.

10. The method of manufacturing a semiconductor laser apparatus according to claim 9, wherein
said first melting point of said first solder layer and said second melting point of said second solder layer are temperatures equal or close to the eutectic point of said Au—Sn alloy in which a content of Au is larger than a content of Sn.

11. The method of manufacturing a semiconductor laser apparatus according to claim 7, wherein
said reaction solder layer formed by reacting said Au in said first electrode with an Au—Sn alloy in said first solder layer has a larger content of Au than said Au—Sn alloy solder layer of said first solder layer and is formed of an Au—Sn alloy reaction solder layer having said third melting point higher than said first melting point of said first solder layer.

12. The method of manufacturing a semiconductor laser apparatus according to claim 1, wherein
said step of forming said second solder layer on said second electrode of said base through said barrier layer includes a step of forming said barrier layer on said second electrode and a step of forming said second solder layer on a surface of said barrier layer inward beyond an outer edge of said barrier layer formed on said second electrode.

13. The method of manufacturing a semiconductor laser apparatus according to claim 1, wherein
a thickness of said barrier layer is smaller than a thickness of said second electrode and a thickness of said second solder layer.

14. The method of manufacturing a semiconductor laser apparatus according to claim 1, wherein
said barrier layer is made of at least one of Pt, Ti, W, Mo and Hf.

15. The method of manufacturing a semiconductor laser apparatus according to claim 1, wherein
said first semiconductor laser device is a semiconductor laser device made of a GaAs-based semiconductor, and
said second semiconductor laser device is a semiconductor laser device made of a nitride-based semiconductor.

16. A semiconductor laser apparatus comprising:
a base including a first electrode and a second electrode formed on a surface thereof, a reaction solder layer formed on said first electrode by reacting a first solder layer having a first melting point with said first electrode, a barrier layer formed on said second electrode and a second solder layer formed on said barrier layer, having a second melting point;
a first semiconductor laser device bonded to said base through said reaction solder layer; and
a second semiconductor laser device bonded to said base through said second solder layer, wherein
a third melting point of said reaction solder layer is higher than said second melting point of said second solder layer.

17. The semiconductor laser apparatus according to claim 16, wherein
said first melting point of said first solder layer is equal or close to said second melting point of said second solder layer and lower than said third melting point of said reaction solder layer.

18. The semiconductor laser apparatus according to claim 16, wherein
said first semiconductor laser device includes a first light-emitting layer from which a laser beam is emitted,
said second semiconductor laser device includes a second light-emitting layer from which a laser beam is emitted, and
a first distance from said first light-emitting layer of said first semiconductor laser device to said base in a height direction, not including a thickness of said barrier layer and a second distance from said second light-emitting layer of said second semiconductor laser device to said base in the height direction, including said thickness of said barrier layer are adjusted to be equal or close to each other so that said first light-emitting layer of said first semiconductor laser device and said second light-emitting layer of said second semiconductor laser device are located at heights equal or close to each other.

19. The semiconductor laser apparatus according to claim 16, wherein
said first semiconductor laser device is a semiconductor laser device made of a GaAs-based semiconductor, and
said second semiconductor laser device is a semiconductor laser device made of a nitride-based semiconductor.

20. An optical apparatus comprising:
a semiconductor laser apparatus including a base having a first electrode and a second electrode formed on a surface thereof, a reaction solder layer formed on said first electrode by reacting a first solder layer having a first melting point with said first electrode, a barrier layer formed on said second electrode and a second solder layer formed on said barrier layer, having a second melting point, a first semiconductor laser device bonded to said base through said reaction solder layer, and a second semiconductor laser device bonded to said base through said second solder layer; and
an optical system controlling a laser beam emitted from said semiconductor laser apparatus, wherein
a third melting point of said reaction solder layer is higher than said second melting point of said second solder layer.
